(19) United States
(12) Patent Application Publication
(10) Pub. No.: US 2022/0302367 A1
(43) Pub. Date: Sep. 22, 2022

(54) SELF POWERED MODULE INTEGRITY INDICATOR USING A PIEZOELECTRIC SENSOR

(71) Applicant: ROHm AND HAAS ELECTRONIC AMTERIALS SINGAPORE PTE, LTD., SINGAPORE (SG)

(72) Inventor: Yinghao TEO, SOUTH WINDSOR (AU)

(21) Appl. No.: 17/616,733

(22) PCT Filed: Jul. 24, 2020
(86) PCT No.: PCT/SG2020/050428

§ 371 Date: Dec. 6, 2021

Related U.S. Application Data
(60) Provisional application No. 62/879,158, filed on Jul. 26, 2019.

(51) Int. Cl. H01L 41/113; B01D 65/10

(52) U.S. Cl. CPC H01L 41/1132; B01D 65/104

(57) ABSTRACT

A device for monitoring the integrity of a membrane module. The device has a piezoelectric sensor capable of generating a voltage when exposed to vibrations and a light emitting diode electrically connected to the piezoelectric sensor, the piezoelectric sensor and the visual indicator being located sufficiently close to the membrane module to sense a vibration.

### BACKGROUND

Hollow fiber or other membrane water treatment apparatus utilize methods to determine whether the fiber or membrane is integral or free of defects. These methods may include a bubble point test where air is used to force water out of the membrane pores. The air pressure required can be correlated to the pore size. Another method is the pressure decay test.

### PRESSURE DECAY TEST (PDT)

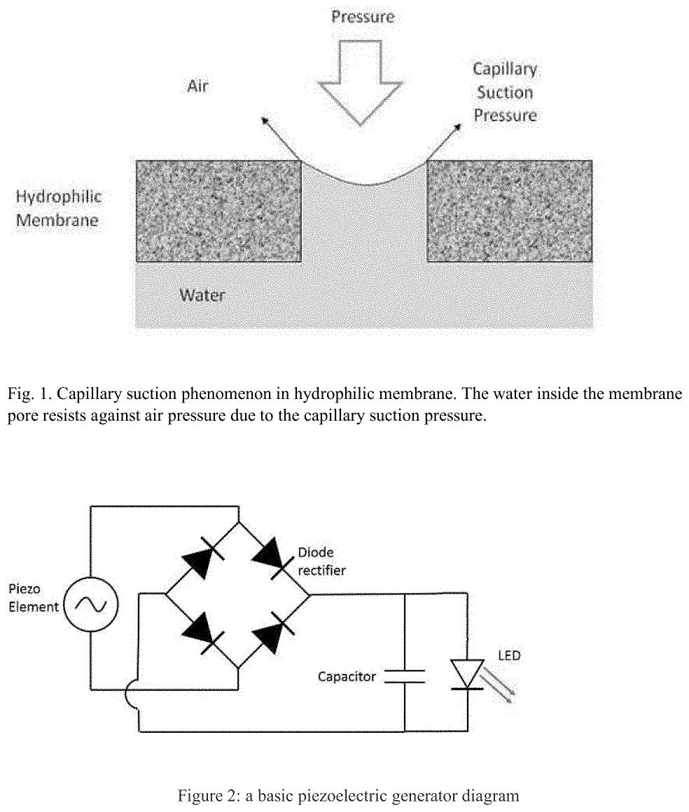

Pressure decay tests (or pressure holding tests) are the most common test methodology used in the field, which are performed in situ at below the bubble point by reversing the permeate flow with pressurized air. Once all the water filled in membrane lumen permeates back through the membrane, membrane lumen is filled up with pressurized air. Due to the capillary suction pressure illustrated in FIG. 1, air does not leak through the membrane as long as pressure is below the bubble point. After isolating the membrane from a pressure source, the lumen pressure is monitored for a predetermined time (5-20 min typical). If there are defects on the membrane surface, air can permeate through the defects and the pressure drops quickly. If there are no defects, only a small amount of air will be lost by the diffusion through the membrane pores.

However, it is not perfectly clear where to set a line between normal pressure decay rate and abnormal pressure decay rate.

Pressure decay tests are particularly useful for the hollow fiber membranes with an integrated skin with support layer. It can be also used for the hollow fiber membranes with non-integrated skin layer and flat sheet membranes, but the maximum allowable air pressure may not be high enough to detect the breaches smaller than, for example, 3-5 micron.

A variation of the pressure decay test involves the use of a microphone or noise sensor that is utilized to detect escaping air from a defective fiber. The current way for module integrity check is to use a sonic analyzer, i.e. microphone, to ‘listen’ and grade the noise level within a module. However, using a microphone requires a power source which might not be readily available.

In one embodiment, Piezoelectric elements could generate electricity from deformation or vibration, and vice versa. A typical circuit that generates electricity from a piezo element is shown in FIG. 2.

This circuit could be made into a box, presumably less than 50 mm×50 mm×10 mm or smaller and attached to the housing of a pressurized hollow fiber module. When a PDT is conducted and a module is not integral, i.e. leaky fibers are present, a lot of noise (vibration) will be generated. This vibration will then be converted to an electrical signal which in turn can be used to power a visual signal such as a light emitting diode (LED).

The proposed way is to provide a visual indicator (via changes in brightness or colors) that is linked to the noise level. The amount of electrical power generated will be proportional to the amount of noise emitting from each module. Thus, the LED indicator can change color or intensity depending on the noise level from a module. This will provide a visual indication on the relative integrity of each module. A greater amount of noise will in turn mean a greater voltage is generated and thus the LED will be illuminated more brightly compared with a low noise output from a module.

The entire piezoelectric assembly may be fabricated onto a circuit board or even an integrated circuit which would become even smaller in size, and lower cost when mass produced.

The main advantage for the proposed indicator will be a time saving for the customer during troubleshooting. The relative noise levels of each module could be viewed from a distance, as compared to the sonic analyzer method which requires physical access to each module.

The phraseology and terminology used herein is for the purpose of description and should not be regarded as limiting. As used herein, the term “plurality” refers to two or more items or components. The terms “comprising,” “including,” “carrying,” “having,” “containing,” and “involving,” whether in the written description or the claims and the like, are open-ended terms, i.e., to mean “including but not limited to.” Thus, the use of such terms is meant to encompass the items listed thereafter, and equivalents thereof, as well as additional items. Only the transitional phrases “consisting of” and “consisting essentially of,” are closed or semi-closed transitional phrases, respectively, with respect to the claims. Use of ordinal terms such as “first,” “second,” “third,” and the like in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

1. A device to monitor the integrity of a membrane module comprising; a piezoelectric sensor capable of generating a voltage when exposed to vibrations and; a visual indicator comprising a light emitting diode electrically connected to the piezoelectric sensor wherein the piezoelectric sensor and the visual indicator are located sufficiently close enough to the membrane module to sense a vibration.
